(19) United States
(12) Patent Application Publication
(10) Pub. No.: US 2016/0168035 A1
(43) Pub. Date: Jun. 16, 2016

(54) ABRASION-RESISTANT OPTICAL PRODUCT WITH IMPROVED GAS PERMEABILITY

(71) Applicant: CPFilms Inc., Fieldale, VA (US)

(72) Inventors: Yuriy Matus, Pleasanton, CA (US); Christian Hermann Stoessel, Santa Rosa, CA (US); Genichi Minase, Dublin, CA (US); Lee Campbell Boman, Belmont, CA (US)

(73) Assignee: CPFILMS INC., Fieldale, VA (US)

(21) Appl. No.: 14/569,966

(22) Filed: Dec. 15, 2014

(51) Int. Cl. C04B 35/14; C23C 16/50; G02B 1/14; C23C 16/40

(52) U.S. Cl. CPC C04B 35/14; C23C 16/401; C23C 16/50; G02B 1/14

(57) ABSTRACT

An optical product for use in products such as window films and electronic displays is disclosed. The optical product includes a polymeric substrate and a hardcoat and has an abrasion resistance at the hardcoat surface as measured by haze increase of no more than 4.5% when measured according to Taber abrasion testing based on ASTM D1044 and a difference in water vapor transmission rate when compared to said polymeric substrate alone of no more than 5 grams/m²/day.

### FIELD OF THE INVENTION

The present invention broadly relates to optical products for use in window film and electronic display applications and methods for their manufacture. More particularly, the present invention relates to an optical product that exhibits a highly desirable and surprising combination of abrasion resistance and gas permeability.

### BACKGROUND OF THE INVENTION

Optical products such as optical films, window films, displays and the like are often manufactured by applying multiple layers of various materials to a polymeric film substrate such as that formed from a polyester such as polyethylene terephthalate. One example of such a coated optical product is described in U.S. Pat. No. 7,229,684, which discloses a multilayer composite film for use in automotive or architectural window film applications. As with many optical products in the art, the product described in the '684 patent includes a protective coating known in the art as a “hardcoat”. This coating layer serves to protect the optical film product, its substrate and components by providing resistance to scratching, abrasion and/or chemical damage.

In addition to a hardness and abrasion resistance sufficient to achieve this protection, it is often also desirable that optical product hardcoats have some level of gas or vapor permeability. For example, an adequate water vapor transmission rate is necessary in certain window film applications so that water from the film application process (that employs a water-activated adhesive at the glass-polymer web interface) can permeate though the polymer substrate and optical product into the atmosphere. Insufficient or slow vapor transmission characteristics can result in longer window film installation drying times and formation of moisture bubbles that interfere with optical quality and aesthetics. Similarly, in electronic display applications, underlying display components may release volatiles over time and, absent adequate permeability, such volatiles can be entrapped and cause fogging, blotches, bubbles and/or other undesirable optical effects.

Hardcoats with suitable gas permeability and gas transmission rate characteristics can be formed from compositions applied by traditional wet coating methods and curable by radiation or heat, for example highly crosslinked acrylic acid esters and particularly radiation polymerizable acrylic coatings such as those disclosed in U.S. Pat. No. 4,557,980. While these wet-applied acrylics are viable for many commercial applications, their level of scratch resistance is limited by the acrylic polymer hardness. Further, the acrylic materials can also suffer from degradation by exposure to ultraviolet radiation, which leads to optical product yellowing, cracking and delamination over time and which requires addition costly UV-stabilizing materials to remedy. Also, wet-applied coatings in the effective hardcoat nanometer or micrometer thickness range may develop coating thickness variations during manufacture that while minute can cause undesirable iridescence in the final optical product. Further, in advanced performance optical product applications that include further coating layers for additional functionality such as anti-reflection or IR reflection, such additional layers require expensive and time-consuming coating techniques such as magnetron sputtering to achieve the desired coating thickness precision and nonetheless can suffer from poor adhesion to the acrylic hardcoat, resulting in premature spalling and delamination especially under tribological conditions for which the hardcoat was designed. Another significant disadvantage of many polymeric hardcoats is their susceptibility to moisture absorption and subsequent swelling, which can introduce unwanted curling of the final product during wet-applied application.

In view of the above, some optical product hardcoats have been formed using inorganic oxides or ceramics applied by conventional sputtering methods, such as described for example in U.S. Pat. No. 6,489,015 B1 and U.S. Pat. No. 5,830,531. Optical products with silicon oxide layers formed by sol-gel and sputtering processes are also generally known, for example as described in U.S. Published Applications 2006/0194453 and 2010/0009195. While these are generally resistant to UV degradation and exhibit adequate hardness to achieve suitable scratch resistance, they can severely reduce the vapor transmission properties of the optical product, resulting in longer drying/installation times for a wet-activated adhesive-applied window films and entrapment of volatiles escaping from underlying components in display applications. Another significant drawback of sputtered hardcoats is the inherent compressive stress in sputtered films, which can impose additional stress on the substrate/coating interface, leading to premature spalling. The compressive stress in sputtered films may also induce substrate curling, which can make these films difficult to convert/laminate and apply in the final product. Further, sputter-coated hardcoats have a relatively slower deposition rate and therefore add to production cost and reduced productivity.

A continuing need therefore exists in the art for an optical product that may be efficiently and cost-effectively manufactured and that meets both the abrasion resistance and gas permeability and transmission demands of current commercial window films, electronic displays and the like while avoiding hardcoat issues such as moisture absorption susceptibility and sputtered hardcoat compressive stress.

### SUMMARY OF THE INVENTION

The present invention addresses this continuing need and achieves other good and useful benefits by providing an optical product including a polymeric substrate and a hardcoat, wherein said optical product has an abrasion resistance at the hardcoat surface as measured by haze increase of no more than 4.5% when measured according to Taber abrasion testing based on ASTM D1044 and a difference in water vapor transmission rate when compared to the polymeric substrate alone of no more than 5 grams/m²/day.

The present invention further relates to method for forming an optical product, said method including applying a ceramic material to a polymeric substrate to form a hardcoat thereon, wherein said applying step includes forming said hardcoat on said polymeric substrate from a gas precursor in the presence of plasma. The resulting optical product is characterized by an abrasion resistance at the hardcoat surface has an abrasion resistance at the hardcoat surface as measured by haze increase of no more than 4.5% when measured according to Taber abrasion testing based on ASTM D1044 and a change in water vapor transmission rate when compared to the polymeric substrate alone of no more than 5 grams/m²/day.

The optical product of the present invention exhibits a highly desirable and surprising combination of abrasion resistance and gas permeability while achieving wet curl reduction and lower compressive stress over prior art hardcoats.

Further aspects of the invention are as disclosed and claimed herein.

### BRIEF DESCRIPTION OF THE DRAWINGS

The invention will be described in further detail below and with reference to the accompanying drawings, wherein like reference numerals throughout the figures denote like elements and in wherein

FIG. 1 is a schematic cross-section of an embodiment of the optical product of the present invention;

FIG. 2 is a schematic cross-section of an embodiment of the optical product of the present invention that includes a spectrally functional layer: and

FIG. 3 is a schematic cross-section of an embodiment of the optical product of the present invention that includes a spectrally functional layer that is a spectral filter.

### DETAILED DESCRIPTION

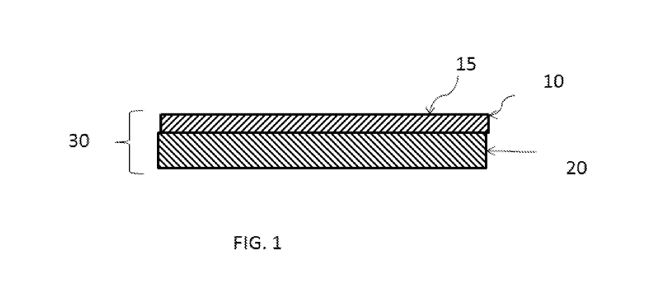

As shown in FIGS. 1 through 3, the present invention is in a first aspect directed to hardcoat 10 which suitable for use with an optical product generally depicted at 30. More particularly, the optical product 30 includes hardcoat 10 with a hardcoat surface 15 and polymeric substrate 20.

The hardcoat 10 preferably includes a ceramic material. Particularly suitable ceramic materials are inorganic, non-metallic material of the structure

R₁—R₂

wherein R₁ is selected from the group consisting of metals, boron, carbon, silicon and germanium and combinations thereof and R₂ is selected from the group consisting of oxide, nitride, carbide, boride, silicide and combinations thereof such as for example, borosilicate and oxynitride. Illustrative examples of ceramic materials for use in the hardcoat 10 include without limitation silicon oxide, silicon nitride, titanium oxide, ZrO₂, CrN, SiC and MoSi and combinations thereof. Suitable hardcoats contain at least 65% by weight ceramic material based on the total weight of the hardcoat.

Preferred ceramic materials to include with hardcoat 10 include ceramic materials selected from the group consisting of silicon oxide, silicon nitride, titanium oxide and mixtures thereof.

An important and advantageous characteristic of the optical product of the present invention is its surprising combination of abrasion resistance and gas permeability. While abrasion resistance can be quantified by a number of different individual test methods or parameters, Taber abrasion testing based on ASTM D1044 and measuring haze and increase in haze upon application of abrasion will be used herein as a suitable quantitative indicia of abrasion resistance. Similarly, while gas permeability can be quantified by a number of different individual test methods or parameters, water vapor transmission rate will be used herein as a suitable quantitative indicia of gas permeability. More particularly, then, optical product 30 of the present invention is characterized by an abrasion resistance at the hardcoat surface as measured by haze increase of no more than 4.5%, preferably no more than 3.5%, more preferably no more than 2.5% and most preferably no more than 2% when measured according to Taber abrasion testing based on ASTM D1044 and a difference in water vapor transmission rate when compared to the polymeric substrate alone (designated here as ΔWVTR) of no more than 5 grams/m²/day, preferably no more than 4 grams/m²/day, more preferably no more than 3 grams/m²/day and most preferably no more than 2 grams/m²/day.

Abrasion resistance is often measured in the art according to a Taber Abrasion test. Taber Abrasion is a test to determine a material's resistance to abrasion. Resistance to abrasion is defined as the ability of a material to withstand mechanical action such as rubbing, scraping, or erosion. Abrasion can be quantified through Taber abrasion by evaluating haze variation (using ASTM D1044). For the present invention, Abrasion testing was performed on 5130 Abraser from Taber Industries for 100 cycles with 500 g weight using a Calibrase CS-10F abrasion wheel.

Water Vapor transmission rate (or WVTR) is typically measured by commercially available measurement devices such as those available from MOCON Inc of Minneapolis, Minn. One suitable such device is the MOCON AquaTran®. For the present invention and in the examples set forth below, WVTR was measured using a MOCON Permatran® 3/60 with testing performed at 37° C. and 100% RH using a sample test area of 10 cm² and results reported in grams/m²/day.

It can be expected that the thickness of the hardcoat 10 will influence optical product abrasion resistance performance, and therefore the overall durability of the optical product 30, as well as the optical product vapor transmission rate. To adequately perform in most commercial applications, the thickness of hardcoat 10 should be at least 0.5 micrometer, more preferably at least 2 micrometers. Hardcoat thicknesses up to a maximum of 5 micrometers may be useful in maximizing scratch resistance while maintaining the desired level of vapor transmission performance such that the hardcoat typically has a thickness of between 0.5 and 5 micrometers. The hardcoat 10 may include a single layer or a plurality of hardcoat layers.

The hard coat surface 15 may also be treated with slip agents or other friction-reducing materials that may improve the overall abrasion resistance of the optical product. Such slip agents, known and conventional in the art, include oxide nanoparticles or antifouling films and are described for example in EP Patent No. 0797111 A2 or in Graphite and Hybrid Nanomaterials as Lubricant Additives by Zhenyu J. Zhang, Dorin Simionesie and Carl Schaschke, Lubricants 2014, 2(2), 44-65.

The polymeric substrate 20 of the optical product of the present invention is preferably a film formed from a thermoplastic such as a polyester and more preferably polyethylene terephthalate (PET). Suitable PET films are commercially available, for example from DuPont Teijin Films under the names Melinex 454 or LJX 112. Other suitable thermoplastics for forming the polymeric substrate 20 include, for example, polyacrylic, polyimides, polyamides such as nylons and polyolefins such as polyethylenes, polypropylenes and the like. The polymeric substrate may include conventional additives such as UV-absorbers, stabilizers, fillers lubricants and the like, blended therein or coated thereon. Preferably, the polymeric substrate 20 is transparent, which generally connotes the ability to perceive visually an object, indicia, words or the like therethrough.

It can be important for overall optical product performance that the refractive index of the hardcoat 10 and its relative relationship to the refractive index of the polymeric substrate 20 be considered and carefully selected. In one embodiment, hardcoat 10 may have a refractive index n_{550 nm} from 1.38 to 1.45. In a more particular embodiment wherein the polymeric substrate is a PET film with a refractive index n_{550 nm} of about 1.6, hardcoat 10 with a refractive index n_{550 nm} from 1.38 to 1.45 provides moderate anti-reflection benefits to the optical product 30.

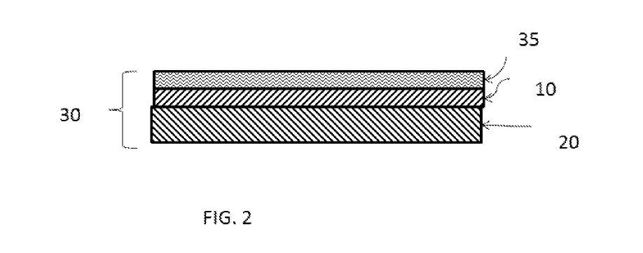

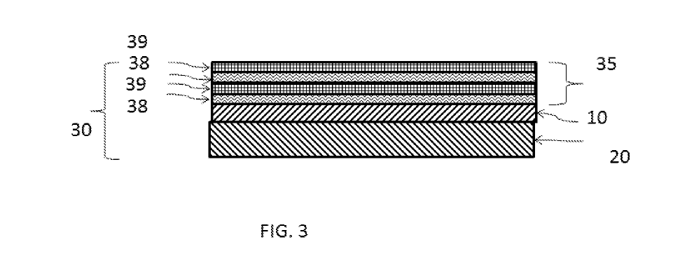

As more particularly shown in FIGS. 2 and 3, the optical product 30 of the present invention may further include a spectrally functional layer 35, preferably arranged such that the hardcoat 10 is between the polymeric substrate 20 and the spectrally functional layer 35. The term “spectrally functional layer” as used herein is defined to mean a layer that imparts a desired optical effect to the optical product of which it is a component. Desired optical effects can be for example, selective electromagnetic reflection, anti-reflection, transmission and/or attenuation. In one embodiment shown in FIG. 2, the spectrally functional layer is an antireflective layer, which in one particularly preferred embodiment has a thickness less than the thickness of the hardcoat 10 and most preferably a refractive index n_{550 nm} lower than the refractive index n_{550 nm} of the hardcoat 10. In one example of this embodiment, the hardcoat 10 may be formed from silicon oxide and the antireflective layer may be formed from magnesium fluoride. In another embodiment shown in FIG. 3, the spectrally functional layer 35 is a spectral filter. A spectral filter typically includes a combination or series of spectral functionally layers 38 and 39, also known in the art as a “stack”, with alternating relatively higher and lower refractive indices and designed to facilitate transmission of energy in certain electromagnetic wave frequencies and reflection in others, for example, an IR-reflecting filter that that also exhibits high visible transmittance as is desirable for thermal management window films. In one example of this embodiment, the hardcoat 10 may be formed from silicon oxide and the spectral filter may be a multilayer structure comprised of silicon oxide layers in combination with alternating layers of materials selected from the group consisting of for example Ti—O, Ta—O, Zr—O, Nb—O, Si—N and others each with a refractive index n_{550 nm} higher than that of hardcoat 10. The design of such stacks is well-known in the art, and depends in part on the choice of coating layer materials, wherein the layer sequence and thickness is a function of the selected materials' refractive indices and their relative relationship. Spectral filters are described for example in Optical Coating Technology by Philip W. Baumeister (SHE Press Monograph Vol. PM137, 2004), which also elaborates that such stacks can also be expanded in layer number and customized so as to perform more complex functions such as signal attenuation.

In another aspect, the present invention is directed to a method for forming an optical product. The method includes applying a ceramic material to a polymeric substrate to form a hardcoat thereon, wherein said applying step includes forming said hardcoat on said polymeric substrate from a gas precursor in the presence of plasma. The resulting optical product has an abrasion resistance at the hardcoat surface as measured by haze increase of no more than 4.5% when measured according to Taber abrasion testing based on ASTM D1044 and a difference in water vapor transmission rate when compared to said polymeric substrate alone of no more than 5 grams/m²/day.

Plasma generation and plasma coating materials, conditions and parameters are known in the art and their selection may vary according to the desired results. Typically, precursor is introduced into the plasma using either a liquid or vapor delivery system to generate precursor gas at a rate of from 20 to 250 sccm. Plasma may be generated using a conventional plasma source and gas selected from the group consisting of O₂, Ar, N₂, He, H₂, H₂O, N₂O or a combination thereof. Typical coatings may be formed using a gas-to-precursor volumetric ratio range of from 1:1 to 50:1.

It will be understood that the gas precursor supplies a ceramic-forming component and the choice of the gas precursor is primarily driven by the desired composition of the hardcoat but is also influenced by a number of processing factors. Suitable gas precursors include metal-organic precursors such as Hexamethyldisiloxane (HMDSO), 1,1,3,3-Tetramethyldisiloxane (TMDSO), tetraethyl orthosilicate (TEOS), silicon tetrahydride or silane (SiH₄), Tetraethoxysilane, Decamethyltetrasiloxane, 1,3-Diethoxy-1,1,3,3-tetramethyldisiloxane, Tris(trimethylsilyl)silane, Hexamethylcyclotrisiloxane, 1,3,5,7-Tetravinyltetramethylcyclotetrasiloxane, Decamethylcyclopentasiloxane, Octamethylcyclotetrasiloxane, Zinc acetate, Diethylzinc, Titanium(IV) isopropoxide, Titanium(IV) ethoxide, Zirconium(IV) ethoxide, Zirconium(IV) ethoxide tert-butoxide, Niobium(V) ethoxide, amines, acetates and beta diketonates of mentioned above compounds. In an embodiment where the ceramic material in the hardcoat is silicon oxide, for example, the gas precursor is preferably selected from the group consisting of HMDSO (Hexamethyldisiloxane), TMDSO (Tetramethyldisiloxane), TEOS (tetraethyl orthosilicate) and SiH₄ (silicon tetrahydride or silane).

While the gas precursor is in the form of a gas (or vapor) during the hardcoat applying step, it will be understood by one of ordinary skill that it may originally be in a liquid or fluid form such that the method of the present invention may optionally include transforming a fluid precursor to gas or vapor form, for example by heating, prior to or simultaneously with the applying step. More specifically, the transforming step may include heating liquid precursor to vaporize the liquid precursor a sufficient amount to create a vapor pressure of typically about at least 10 Torr. The process may include combining the gas precursor with a carrier gas to form a precursor/carrier gas mix, for example in a bubbler arrangement, preferably further including measuring and regulating the flow of the precursor/carrier gas mix with suitable methods and equipment such as with a mass flow controller.

In certain embodiments of the method of the present invention, it will be understood that the amount of ceramic-forming component, such as nitrogen or oxygen, available from the gas precursor is insufficient to properly apply a ceramic material to the polymeric substrate to form a hardcoat thereon. In such embodiments, the method of the present invention further includes supplying a precursor-reactive gas, for example oxygen, nitrogen, ammonia, water, nitrous oxide or combinations thereof, as part of the supplying step, and supplying energy sufficient to initiate reaction between the gas precursor and the precursor-reactive gas. A noble gas such as argon may also be supplied to assist the reaction. Most preferably, the method of the present invention is a plasma-enhanced chemical vapor deposition (PECVD) process and follows conventional plasma-enhanced chemical vapor deposition (PECVD) process steps and parameters as known in the art and described for example in Peter M. Martin (ed.), Handbook of Deposition Technologies for Films and Coatings: Science, Applications and Technology (3^{rd} edition. William Andrew/Elsevier, Oxford, UK, 2009).

The following examples, while provided to illustrate with specificity and detail the many aspects and advantages of the present invention, are not be interpreted as in any way limiting its scope. Variations, modifications and adaptations which do depart of the spirit of the present invention will be readily appreciated by one of ordinary skill in the art.

### Example 1

Several samples of the optical product of the present invention were produced using a PECVD process with HMDSO or TMDSO employed as gas precursors to produce a hardcoat formed from silicon oxide. All samples were produced on a laboratory roll-to-roll coater with 75 micrometer thick PET film employed as the polymeric substrate. Typical substrate width of the roll coater is 300 mm. PECVD process details are as follows: Precursor is introduced into the plasma using a liquid delivery system. Precursor gas ran at a rate of 113 sccm. Plasma is generated using a dual magnetron plasma source and oxygen gas. Gas-to-precursor ratio was 1 HMDSO:10 O₂.

The samples produced are listed in Table 1 below:

TABLE 1

| Sample No. | Precursor | Hardcoat | Thickness, μm |
|---|---|---|---|
| 1 | HMDSO | SiO | 2.4 |
| 2 | HMDSO | SiO | 2.4 |
| 3 | HMDSO | SiO | 2.4 |

The samples described above were then tested for three commercially important performance parameters. Firstly, adhesion of the hardcoat to the polymeric substrate is measured by a cross-hatch tape test performed according to ASTM D3359. A test result value of 5B (corresponding to smooth cuts by cutting device and no flaking) is indicative of acceptable commercial performance. Secondly, abrasion resistance of the optical product hardcoat surface is measured according to a Taber abrasion testing method using ASTM D1044. Tests were performed using a Model 5130 Abraser from Taber Industries for 100 cycles with 500 g weight using a Calibrase CS-10F abrasion wheel.

Water Vapor Transmission Rate (WVTR) of the samples was measured using a MOCON Permatran® 3/60 with testing performed at 37° C. and 100% RH using a sample test area of 10 cm² and results reported in g/m²/day. WVTR of an uncoated 75 micrometer-thick reference PET film was also measured as a control and found to be 9.29 grams/m²/day. Difference in water vapor transmission rate (ΔWVTR) is then calculated as WVTR of the sample subtracted from WVTR of the uncoated control PET film. The results of this testing is set forth in Table 2 below:

TABLE 2

| | | Abrasion Resistance, | ΔWVTR, |
|---|---|---|---|
| Sample No | Adhesion | Haze Increase (%) | grams/m²/day |
| 1 | 5B | 4.02 | 2.73 |
| 2 | 5B | 1.79 | 2.90 |
| 3 | 5B | 4.19 | 4.59 |

A person skilled in the art will recognize that the measurements described herein are measurements based on publicly available standards and guidelines and can be obtained by a variety of different specific test methods. The test methods described represents only one available method to obtain each of the required measurements.

The foregoing description of various embodiments of the invention has been presented for purposes of illustration and description. It is not intended to be exhaustive or to limit the invention to the precise embodiments disclosed. Numerous modifications or variations are possible in light of the above teachings. The embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

That which is claimed is:

1. An optical product comprising a polymeric substrate, a hardcoat and a hardcoat surface, wherein said optical product has an abrasion resistance at said hardcoat surface as measured by haze increase of no more than 4.5% when measured according to Taber abrasion testing based on ASTM D1044 and a difference in water vapor transmission rate when compared to said polymeric substrate alone of no more than 5 grams/m²/day.

2. The optical product of claim 1 wherein the polymeric substrate is transparent.

3. The optical product of claim 2 wherein the polymeric substrate is formed from polyethylene terephthalate.

4. The optical product of claim 1 wherein said hardcoat comprises a plurality of hardcoat layers.

5. The optical product of claim 1 wherein said hardcoat comprises a ceramic material.

6. The optical product of claim 5 wherein said hardcoat contains at least 65% by weight of said ceramic material based on the total weight of the hardcoat.

7. The optical product of claim 5 wherein said ceramic material is an inorganic non-metallic material with the structure
R₁—R₂
wherein R1 is selected from the group consisting of metals, boron, carbon, silicon and germanium and combinations thereof and R2 is selected from the group consisting of oxide, nitride, carbide, boride, silicide and combinations thereof.

8. The optical product of claim 5 wherein said ceramic material is selected from the group consisting of silicon oxide, silicon nitride, titanium oxide, ZrO2, CrN, SiC and MoSi and combinations thereof.

9. The optical product of claim 1 wherein said hardcoat has a refractive index (n550 nm) of from 1.38 to 1.45.

10. The optical product of claim 1 wherein said hardcoat has a thickness of between 0.5 and 5 micrometers.

11. The optical product of claim 1 further comprising a spectrally functional layer.

12. The optical product of claim 11 wherein said spectrally functional layer is an anti-reflective layer.

13. The optical product of claim 11 wherein said spectrally functional layer is a spectral filter.

14. The optical product of claim 11 wherein said hardcoat is between said polymeric substrate and said anti-reflective layer.

15. The optical product of claim 12 wherein said anti-reflective layer has a has a thickness less than the thickness of said hardcoat.

16. The optical product of claim 15 wherein said antireflective layer has a refractive index n550 nm lower than the refractive index n550 nm of the hardcoat.

17. A method for forming an optical product, said method comprising applying a ceramic material to a polymeric substrate to form a hardcoat thereon, wherein said applying step includes forming said hardcoat on said polymeric substrate from a gas precursor in the presence of plasma and wherein said optical product has an abrasion resistance at the hardcoat surface as measured by haze increase of no more than 4.5% when measured according to Taber abrasion testing based on ASTM D1044 and a difference in water vapor transmission rate when compared to said polymeric substrate alone of no more than 5 grams/m²/day.

18. The method of claim 17 further comprising transforming a fluid precursor to gas prior to or simultaneously with said applying step.

19. The method of claim 17 further comprising supplying a precursor-reactive gas as part of said applying step and supplying energy sufficient to initiate reaction between the gas precursor and the precursor-reactive gas.
